(19) United States
(12) Patent Application Publication
(10) Pub. No.: US 2008/0026548 A1
(43) Pub. Date: Jan. 31, 2008

(54) Film Forming Apparatus and Film Forming Method

(76) Inventors: Noriaki Tani, Sanbumachi (JP); Taizo Morinaka, Sanbumachi (JP); Toshihiro Suzuki, Sanbumachi (JP); Masahiro Matsumoto, Sanbumachi (JP)

Correspondence Address: ARENT FOX LLP, 1050 CONNECTICUT AVENUE, N.W., SUITE 400, WASHINGTON, DC, 20036, US

(21) Appl. No.: 11/547,724

(22) PCT Filed: Mar. 29, 2005
(86) PCT No.: PCT/JP05/05942

§ 371 Date: Jun. 21, 2007

(30) Foreign Application Priority Data
Apr. 9, 2004 (JP) 2004-115196
Jun. 28, 2004 (JP) 2004-189738

(51) Int. Cl. H01L 21/02; H01L 21/20

(52) U.S. Cl. 438/494; 118/723 CB; 257/E21.001

(57) ABSTRACT

An optical film having a thin film stacked and optical characteristics close to design values is provided. In a vacuum chamber (2), a rotating drum (3) holding a substrate (4), an Si target (22) for forming a metal film on a film forming plane of the substrate (4), a Ta target (23), and an ECR reaction chamber (30) for reacting the metal film to a reaction gas by plasma, are provided. A film forming apparatus (51) is provided with an ion gun (11) for accelerating reaction of the film formed on the film forming plane by irradiating the film forming plane with ion beams, and the metal film formation, the gas reaction and the reaction acceleration by using ion beams are repeatedly performed.

### TECHNICAL FIELD

The present invention relates to a film forming apparatus and a film forming method to form a film such as a metal film and a dielectric film on a film forming plane (surface) of a substrate, and in particular, a film forming apparatus and a film forming method to form a film with high smoothness. The present invention also relates to a film forming apparatus and a film forming method to form a uniform and smooth film on a surface of a substrate with irregularity such as a groove.

### BACKGROUND ART

A method to form an optical film for example by sputtering is widely used, and in the method, a plurality of thin films are often stacked to obtain a desired optical characteristics. Especially recently, the request for optical characteristics with high accuracy tends to increase the number of films to stack and the thickness of the entire optical film. To meet the tendency, forming a film having high optical characteristics with a low light absorption coefficient (high light transmittance) and having a smooth surface is needed.

In the semiconductor field, an aspect ratio (depth/hole diameter or groove width) of a contact hole or a wiring groove which is formed on a substrate is being increased more and more to increase a packaging density. And also, for a semiconductor wiring using copper for example, a barrier layer or a seed layer for electrolytic plating needs to be formed in the hole or inside (side walls and bottom surface) of the groove.

Sputtering is a known method to form a film on a substrate with such irregularity on the surface thereof such as those described in Japanese Patent Laid-Open No. 8-264487, pp. 5-10, FIG. 2 and FIG. 3, and Japanese Patent No. 2602276, pp. 4-6, FIG. 1 and FIG. 13.

Meanwhile, attention is currently focused on optical elements to stack excellent optical films on a substrate having a surface with steps thereon. For such optical elements, an optical film is essential which has an excellent coatability to follow the steps of the surface, a very low absorption or a diffused reflection of light, that is, a high light transmittance, and a high surface smoothness.

When a plurality of thin films are stacked for an optical film for example, the stacked films often do not yield the optical characteristic as designed, because the surface of each thin film is not smooth (flat), and the films slightly absorb light. In the view of the above problem, it is an object of the present invention to form an optical film having a thin film stacked and optical characteristics close to design values by forming the thin films successively with ion beams being irradiated to each thin film.

Sputtering a substrate having a surface with irregularity causes an overhang (film form to close the opening) to be formed at the shoulder of a recess of the irregularity (opening edge), and the overhang blocks sputtered particles from reaching the sidewalls and bottom surface of the recess. Thus a film of a desired thickness is not formed uniformly at the sidewalls and bottom surface of the recess, which results in a poor filling characteristics when a wiring or optical thin film is filled in the recess. Also an adequate coverage (a uniform film forming which follows the irregularity) over the substrate surface with irregularity will not be achieved. If the surface roughness of the film which is formed on the substrate is large, the light transmittance is lowered, which increases an optical loss.

So, it is an object of the present invention to provide a film forming apparatus to form a film with high light transmittance and high surface smoothness by irradiating an ion beam to a surface of a substrate where the film is to be formed to accelerate the reactivity of the film when a dielectric film is formed.

It is another object of the present invention to provide a film forming apparatus to form a film with good filling characteristics and good coverage and also with small surface roughness by optimizing the type of gas to irradiate with an ion gun and the accelerating voltage of an ion beam to the substrate having a surface with irregularity.

### DISCLOSURE OF INVENTION

To achieve the above objects, the present invention provides a film forming apparatus, and the film forming apparatus according to claim 1 comprises: in an evacuatable vacuum chamber, a holding member to hold a substrate; film forming means to form a thin film on the substrate; reacting means to react the thin film with a reaction gas by plasma; and an ion gun to irradiate an ion beam to the substrate, and is configured to form a thin film stack by one of accelerating of the reaction between the thin film and the reaction gas and etching of a portion of the thin film, or by both of them.

The film forming apparatus according to claim 2 is characterized in that the holding member is a tubular rotating drum which rotates on its axis, and the substrate is held on the outer circumferential surface of the rotating drum.

The film forming apparatus according to claim 3 is characterized in that the holding member is a flat plate type rotary disk which rotates on its axis, and the substrate is held on the plate surface of the rotary disk.

The film forming apparatus according to claim 4 is characterized in that a plurality of film forming means are provided.

The film forming apparatus according to claim 5 is characterized in that the film forming means and the reacting means form one of an oxide film and a nitride film, or both of them.

The film forming apparatus according to claim 6 is characterized in that the film forming means is sputtering means.

The film forming apparatus according to claim 7 is characterized in that an accelerating voltage applied to the ion gun is 500 V to 3,000 V.

The film forming apparatus according to claim 8 is characterized in that the gas to produce the ion beam is one of an oxidizing gas to supply oxygen ions and a nitriding gas to supply nitrogen ions.

The film forming apparatus according to claim 9 is characterized in that the ion beam is generally perpendicularly irradiated to the substrate.

The film forming apparatus according to claim 10 is characterized in that the ion beam is irradiated toward the thin film which blocks a thin film deposition into a recess of an irregular surface of the substrate.

In the film forming apparatus with such a configuration, a process for forming a thin film such as a metal film and a process for accelerating a reaction by gas reaction and ion beams and etching are performed repeatedly, so that the projections which form the roughness of the film are etched to provide small surface roughness as well as the gas reaction is accelerated by ion beams to form a good characteristic film.

A film forming method according to claim 11 of the present invention is characterized in that the method comprises: a film forming step to form a thin film on a substrate which is held by a holding member in an evacuatable vacuum chamber; a reacting step to react the formed thin film with a reaction gas by plasma; and an irradiating step to irradiate an ion beam by an ion gun to the substrate, and the irradiating step further comprises forming a thin film stack by one of accelerating the reaction between the thin film and the reaction gas and etching a portion of the thin film, or by both of them.

In addition to the above configuration, a film forming method according to claim 12 is characterized in that the holding member is a tubular rotating drum which rotates on its axis, and the substrate is held on the outer circumferential surface of the rotating drum, and the thin film is formed and stacked in the film forming step, the reacting step, and the irradiating step while rotating the rotating drum.

The film forming method according to claim 13 is characterized in that the holding member is a flat plate type rotary disk which rotates on its axis, and the substrate is held on the plate surface of the rotary disk, and the film forming step, the reacting step, and the irradiating step are performed to form and stack the thin film while rotating the rotating drum.

The film forming method according to claim 14 is characterized in that the thin film forming step is a step to form a plurality of thin films by a plurality of film forming means.

The film forming method according to claim 15 is characterized in that one of an oxide film and a nitride film, or both of them are formed in the film forming step and the reacting step.

The film forming method according to claim 16 is characterized in that the film forming step is the step to form a thin film by sputtering.

The film forming method according to claim 17 is characterized in that an accelerating voltage applied to the ion gun is 500 V to 3,000 V.

The film forming method according to claim 18 is characterized in that the gas to produce an ion beam is one of an oxidizing gas to supply oxygen ions and a nitriding gas to supply nitrogen ions.

The film forming method according to claim 19 is characterized in that the ion beam is generally perpendicularly irradiated to the substrate.

The film forming method according to claim 20 is characterized in that the ion beam is irradiated toward the thin film which blocks a thin film deposition into a recess of an irregular surface of the substrate.

In the film forming method, a portion of a thin film is etched by ion beam irradiation so that an overhang which is formed at a shoulder of a recess is etched (removed) to enlarge the opening of the recess. This makes easier for sputtered particles to reach the sidewalls and bottom surface of the recess, resulting in successfully forming a film on the sidewalls and bottom surface. As a result, a good coverage over the substrate surface is achieved, and a film of a desired thickness is formed on the bottom surface of the recess uniformly which leads to a good filling characteristics. In addition, the projections which form the film roughness are etched, resulting in a small surface roughness.

According to the film forming apparatus and the film forming method of the present invention, a process for forming a thin film such as a metal film and a process for reaction accelerating by gas reaction and ion beams and etching are performed repeatedly, so that a small surface roughness is achieved and a good characteristic film is formed.

Moreover, a film with good filling characteristics, good coverage, and also a small surface roughness is formed on a substrate having a surface with irregularity. Advantageously, the apparatus has a simple configuration with an added ion gun.

In addition, the repetition of forming a film and etching it enables films with good filling characteristics and good coverage to be successively formed.

### BRIEF DESCRIPTION OF DRAWINGS

FIG. 1 is a schematic plane view to show a film forming apparatus according to a first embodiment;

FIG. 2 is a schematic cross-sectional view to show a configuration of an ion gun of the film forming apparatus according to the first embodiment;

FIG. 3 is a chart to show a surface roughness of a film of the first embodiment;

FIG. 4 is a graph to show a transmittance of a film in the first embodiment;

FIG. 5 is a graph to show a light absorption coefficient per layer of a film, and a surface roughness after stacking of 23 layers in a second embodiment;

FIG. 6 is a schematic plane view to show a film forming apparatus according to a third embodiment;

FIG. 7 is a cross-sectional view to show a film profile formed on a first substrate without the operation of an ion gun in the third embodiment;

FIG. 8 is a cross-sectional view to show a film profile formed on a second substrate without the operation of an ion gun in the third embodiment;

FIG. 9 is a cross-sectional view to show a film profile formed on a first substrate with the operation of an ion gun in the third embodiment;

FIG. 10 is a cross-sectional view to show a film profile formed on a second substrate with the operation of an ion gun in the third embodiment;

FIG. 11 is a cross-sectional view to show a film profile formed on a third substrate with an Ar gas 30 sccm flow through an ion gun in a fourth embodiment;

FIG. 12 is a cross-sectional view to show a film profile formed on a third substrate with an Ar gas 10 sccm flow and an O₂ gas 20 sccm flow through an ion gun in the fourth embodiment;

FIG. 13 is a cross-sectional view to show a film profile formed on a third substrate with an O₂ gas 30 sccm flow through an ion gun in the fourth embodiment;

FIG. 14 is a graph to show a transmittance of the film profile shown in FIG. 11 in the fourth embodiment;

FIG. 15 is a view to show a transmittance of the film profile shown in FIG. 12 in the fourth embodiment; and

FIG. 16 is a view to show a transmittance of the film profile shown in FIG. 13 in the fourth embodiment.

### DESCRIPTION OF SYMBOLS

1, 51 film forming apparatus
2 vacuum chamber
3 rotating drum (holding member)
4 substrate
5 Ni target
11 ion gun
12 gas introducing inlet port for ion gun
22 Si target
23 Ta target
24, 25 sputtering cathode
28, 29 sputtering gas introducing inlet port
30 ECR reaction chamber (reacting means)
31 reaction gas introducing inlet port

### BEST MODE FOR CARRYING OUT THE INVENTION

Now, several embodiments of the present invention will be explained.

### Embodiment 1

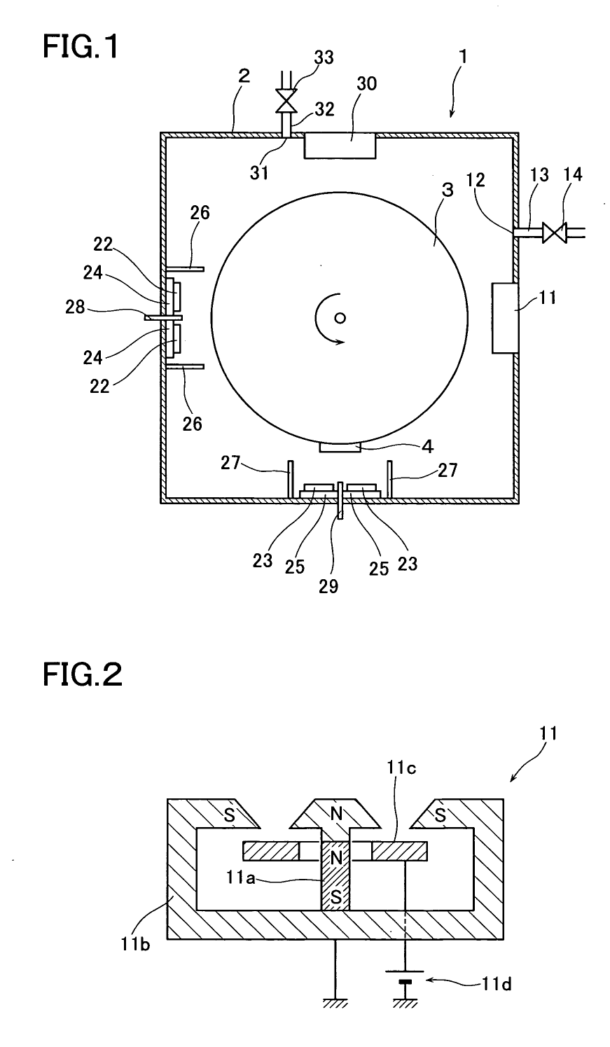

FIG. 1 is a schematic plane view to show a film forming apparatus 1 according to this embodiment.

The film forming apparatus 1 is a carousel type sputtering film forming apparatus which includes a vacuum chamber 2, and a tubular rotating drum 3 which is installed in the center of vacuum chamber 2 rotatably around the central axis thereof. The rotating drum 3 has an outer circumferential surface where a substrate 4 is held so that the surface of the substrate 4 (deposition face) faces toward the open space around the drum.

The vacuum chamber 2 has two sides provided with Si targets 22 and Ta targets 23 respectively, and each targets 22, 23 are respectively configured integrally with a sputtering cathode 24, 25 which are connected to an external alternating current power source which is placed out of the figure. Near the Si targets 22 and the Ta targets 23, deposition preventive plates 26, 27 are disposed respectively to surround the space in front of the rotating drum 3. Between the Si targets 22 and between the Ta targets 23, sputtering gas introducing inlet ports 28, 29 are provided respectively.

The vacuum chamber 2 has another side opposed to the Ta target 23 where an ECR reaction chamber 30 (reacting means) is provided to cause a reaction gas (O₂ in this embodiment) to be reacted with the metal film formed by the targets 22 and 23 by plasma. Near the ECR reaction chamber 30 is provided with a reaction gas introducing inlet port 31 which is connected to an introducing tube 32 with a conductance valve 33 mounted thereto.

The vacuum chamber 2 has another side opposed to the Si targets 22 where an ion gun 11 is provided to irradiate an ion beam. The ion gun 11 is disposed to oppose to the substrate 4 which rotates with the rotating drum 3 so that the ion beam from the ion gun 11 is generally perpendicularly irradiated to the surface of the substrate 4. Near the ion gun 11 in the vacuum chamber 2 is provided a gas introducing inlet port 12 for the ion gun, which is connected to an introducing tube 13 with a conductance valve 14 mounted thereto.

The ion gun 11 in this embodiment has a configuration as shown in FIG. 2. The ion gun 11 includes: a permanent magnet 11a; an iron yoke 11b surrounding the permanent magnet 11a and having openings, at both ends of the openings leaked magnetic fields being generated; a doughnut shaped anode electrode 11c which is disposed near the leaked magnetic fields; and a power source 11d for an accelerated voltage, and when a positive voltage is applied to the anode electrode 11c by the power source 11d, plasma is generated at the leaked magnetic fields. Then the O⁺ ions and Ar⁺ ions are repulsed out by the positive anode electrode 11c and accelerated to be irradiated toward the substrate 4. While in this embodiment a linear ion gun 11 is used with an opening in the form of line loop, an ion gun may be used which has a grid shaped electrode having a flat plane with multiple holes therein.

Now, a result of a film forming process to a surface of the substrate 4 with the film forming apparatus 1 of the above configuration will be shown below.

First, the vacuum chamber 2 is evacuated to 10⁻³ Pa and an Ar gas 30 sccm is introduced through each of the sputtering gas introducing inlet port 28, 29, an O₂ gas 100 sccm is introduced through the reaction gas introducing inlet port 31, and an O₂ gas 30 sccm is introduced through the gas introducing inlet port for an ion gun 12. This raises the pressure near the targets 22 and 23 to 0.3 Pa, and the pressure in the oxidizing chamber (the remained space) to 0.2 Pa.

Next, the rotating drum 3 is rotated at 200 rpm and a microwave source of the ECR reaction chamber 30 is applied with 1 kW to generate oxide plasma. The ion gun 11 is applied with 110 W (1,400 V-0.08 A) to generate an ion beam. Subsequently, the sputtering cathode 24 is applied with AC 5 kW to start sputtering until a SiO₂ film of a predetermined thickness is formed. Similarly, the sputtering cathode 25 is applied with AC 5 kW to start sputtering until a Ta₂O₅ film of a predetermined thickness is formed.

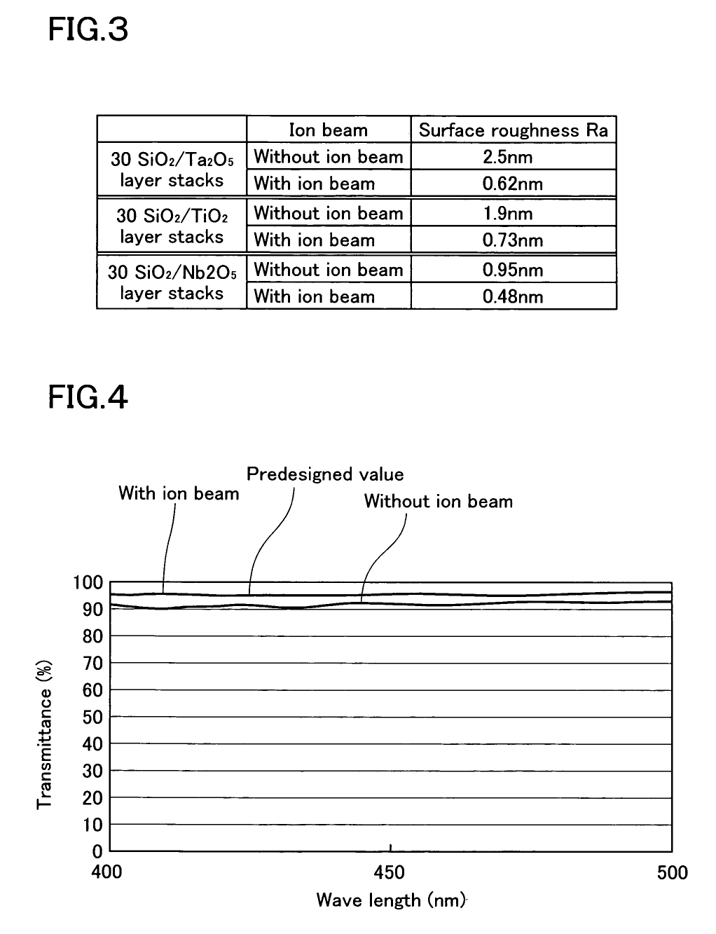

In this way, the forming of a SiO₂ film and a Ta₂O₅ film by sputtering, the oxidation reaction with the ECR reaction chamber 30, the acceleration of the oxidation reaction by the ion gun 11, and the etching of the film surface are performed repeatedly to form an optical multi-layered film (30-layer stacks) on a surface of the substrate 4 as optically predesigned. The obtained results are shown in FIG. 3 and FIG. 4. For controls, the results without the operation of ion gun 11 are also shown in FIG. 3 and FIG. 4.

FIG. 3 shows the surface roughness of a film (center line average roughness Ra) with/without the operation of ion gun 11. In FIG. 3, the results for a SiO₂/TiO₂ film and a SiO₂/Nb₂O₅ film (30-layer stack each) are also shown in addition to the result for a SiO₂/Ta₂O₅ film. As seen clearly from FIG. 3, a smaller surface roughness is obtained with the operation of the ion gun 11 compared to that without the operation of the ion gun 11.

FIG. 4 shows optical characteristics of the optical multi-layered film which is measured with a spectrophotometer, that is, it shows a transmittance for the light having a wave length of 400 to 500 nm. As seen clearly from FIG. 4, a higher transmittance and a value closer to the predesigned value (transmittance) is obtained with the operation of the ion gun 11 compared to that without the operation of the ion gun 11. This means the ion beam irradiation allows a film with a higher transmittance and a smaller optical loss to be formed.

In this way, the operation of the ion gun 11 yields a smaller surface roughness and a higher transmittance of a film, because the ion beam irradiation etches the projections forming the film roughness to reduce the surface roughness, and the reduced surface roughness results in a smaller light scattering at the surface and a higher transmittance.

Around the ion beam from the ion gun 11, there is produced plasma emission, and this plasma contributes the oxidation reaction of a metal film with the plasma from the ECR reaction chamber 30.

In this embodiment, the film forming, the reaction acceleration and etching by the ion gun 11, and the oxidation reaction by the ECR reaction chamber 30 are serially repeated, however, the film forming, the oxidation reaction by the ECR reaction chamber 30, and the reaction acceleration and etching by the ion gun 11 may be serially repeated in this order.

Meanwhile, the ion beam by the ion gun 11 desirably has a beam energy with an energy distribution mainly in the range of 500 eV to 3,000 eV. This range is desirable because etching with the energy less than 500 eV is not effective, and etching with the main energy over 3,000 eV will be an excess work which lowers the film forming rate.

In this embodiment, an O₂ gas having a feature to accelerate the oxidation reaction is used to produce an ion beam, however, other reactivity gases which contain an oxidizing gas to supply oxygen ions such as O₃, N₂O, CO₂, H₂O may be used. When a nitride film is formed, a reactivity gas which contains a nitriding gas to supply nitrogen ions such as N₂ and NH₃ may be used.

While in this embodiment the substrate 4 is held on an outer circumferential surface of a carousel type rotating drum 3, the substrate 4 may be held on a rotary disk. For example, a flat plate type rotary disk which rotates about its central axis may be the holding member to hold the substrate 4 on a plate surface of the rotary disk with the surface of the substrate 4 facing toward the open space around the disk.

Also while in this embodiment, two sputtering cathodes 24, 25 (sputtering means), one ion gun 11, and the ECR reaction chamber 30 are provided, less of more of these elements may be provided depending on the required film thickness, the film forming rate, the number and size of substrates and the like.

### Embodiment 2

In this embodiment, a film forming process was performed with the film forming apparatus 1 according to Embodiment 1 by applying a different accelerating voltage from that in Embodiment 1 to the ion gun 11. That is, with the accelerating voltages of 0 V (no operation), 700 V, 1,400 V, and 2,800 V being applied to the ion gun 11, the film forming process, the oxidation reaction process by the ECR reaction chamber 30, and the reaction acceleration and etching process by the ion gun 11 were performed repeatedly to form an optical multi-layered film (23-layer stack).

The light absorption coefficient per layer of a film formed with the above accelerating voltages, and the surface roughness after stacking of 23 layers are shown in FIG. 5. The light absorption coefficient was measured at the wave length of 400 nm. The actual energy obtained from the accelerating voltage applied to the ion gun 11 has an energy distribution with gentle slopes on both side of the accelerating voltage as the center thereof (a distribution like a normal distribution), and the peak amount of energy was almost equal to the accelerating voltage.

As shown in FIG. 5, while the light absorption coefficient is 0.3% when the ion gun 11 is not operated at 0 V, the absorption coefficient is less than 0.3% at the accelerating voltages of 700 V, 1,400 V, and 2,800 V, which shows the ion beam improves the oxidizing reactivity of the film (the reaction is accelerated). However, the absorption coefficient tends to increase at the voltage over 1,400 V. This is attributed to the fact that while the O⁻ ions enter into the film with some energy by the accelerating voltage in an area where the incident energy is lower, increasing the reactivity on the film surface, while as the accelerating voltage (incident energy) is increased, the O⁻ ions which is accelerated to a higher speed than the oxygen bonding energy take away the oxygen from the outmost surface of the formed dielectric film.

Meanwhile, the surface roughness is found to be reduced as the accelerating voltage is increased. This is assumed to be due to the improved migration (mobility) of sputtered particles by swinging the atoms on the substrate surface, and due to the etching of the projections on the film surface, accompanying with the increase of the ion beam energy.

From the above description, it can be seen that in order to form a film with a high light transmittance and a smooth surface, the accelerating voltage applied to the ion gun 11 is desirably on the order of from 500 V to 3,000 V.

### Embodiment 3

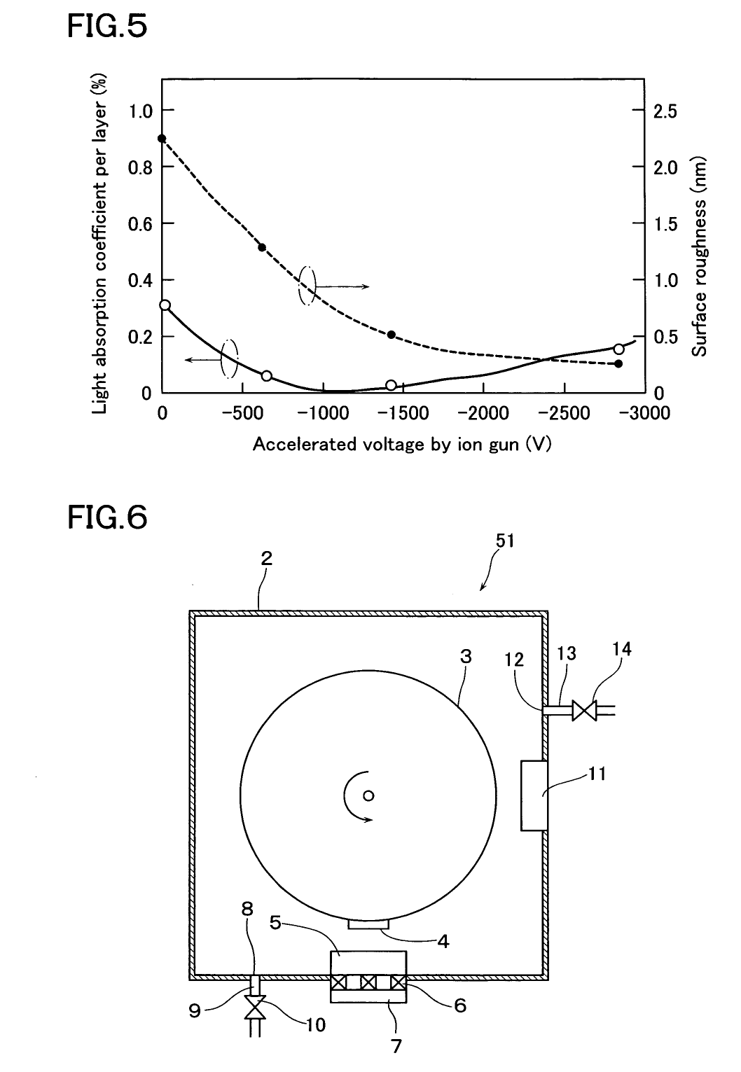

FIG. 6 is a schematic plane view to show a film forming apparatus 51 according to this embodiment. The same elements as those used in the film forming apparatus according to Embodiment 1 are denoted by the same reference numerals.

The vacuum chamber 2 includes a side where a Ni target 5 is disposed to oppose to a substrate 4 which rotates with the rotation of a rotating drum 3. The Ni target 5 is a plate having a width 135 mm, a length 400 mm, and a thickness 3 mm, and is formed integrally with a sputtering cathode 7 through a magnetic circuit 6. Near the Ni target 5 in the vacuum chamber 2 is provided a sputtering gas introducing inlet port 8, which is connected to an introducing tube 9 with a conductance valve 10 mounted thereto.

The ion gun 11 to irradiate an ion beam is provided at a position where the Ni target 5 is rotated by 90 degree about the rotating drum 3. The ion gun 11 is disposed to oppose to the substrate 4 which rotates with the rotating drum 3 so that the ion beam from the ion gun 11 is generally perpendicularly irradiated to the surface of the substrate 4. Near the ion gun 11 in the vacuum chamber 2 is provided a gas introducing inlet port for the ion gun 12, which is connected to an introducing tube 13 with a conductance valve 14 mounted thereto.

Now, results of a film forming process to a surface of the substrate 4 having irregularity with the film forming apparatus 51 of the above configuration will be shown below.

First, the vacuum chamber 2 is evacuated to 10⁻³ Pa and an Ar gas 10 sccm is introduced through the sputtering gas introducing inlet port 8 to raise the pressure in the vacuum chamber 2 to 0.3 Pa. And an Ar gas 25 sccm is introduced through the gas introducing inlet port for ion gun 12 and the rotating drum 3 is rotated at 20 rpm. In this condition, the sputtering cathode 7 is applied with 5 kW to start sputtering.

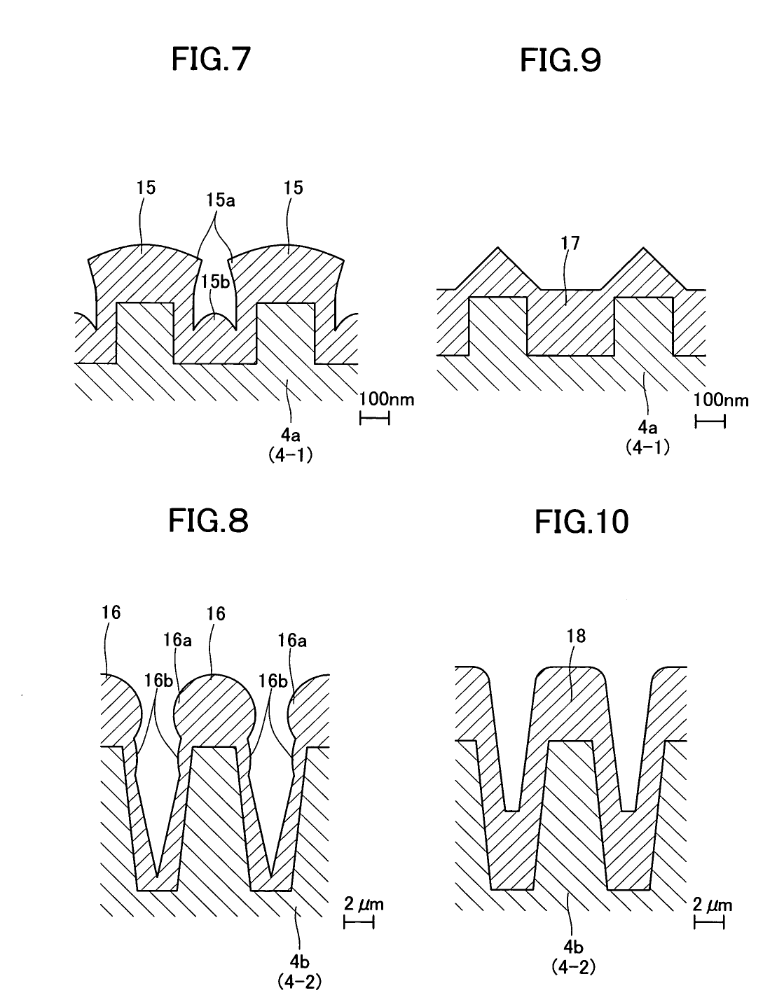

As for the substrate 4, a substrate 4-1 having fine irregularity 4a of a relatively small aspect ratio as shown in FIG. 7 and FIG. 9, and a substrate 4-2 having irregularity 4b of a relatively large aspect ratio as shown in FIG. 8 and FIG. 10 were used.

First, the results of a film forming process without the operation of ion gun 11 (without a power applied) are shown in FIG. 7 and FIG. 8.

When a Ni film 15 having a thickness 200 nm was formed on the substrate 4-1, as shown in FIG. 7, the projections of the irregularity 4a had so much deposition of a Ni film 15 that overhangs 15a were formed at both ends of the projections (at the shoulders of the recesses). In the central bottom surfaces of recesses of the irregularity 4a, there formed bumps 15b of the Ni film 15, which made the film thickness in the recesses non-uniform. This is because the overhangs 15a closed the openings of the recesses and many sputtered particles (Ni) were deposited on the centers of the recesses. Due to the non-uniform thickness of the film in the recesses, wiring cannot be stably filled in the recesses.

When a Ni film 16 having a thickness 500 nm was formed on the substrate 4-2, as shown in FIG. 8, the projections of the irregularity 4b had so much deposition of a Ni film 16 that ball-like overhangs 16a were formed on the tops of the projections, and bump-like depositions 16b were formed right under the overhangs 16a. The Ni film 16 which was formed inside of recesses of the irregularity 4b had a relatively small thickness, and especially the film on the bottom surface was very thin. This is because the overhangs 16a and the depositions 16b closed the openings of the recesses and most of the sputtered particles which entered into the recesses were attached to the sidewalls of the recesses, and did not reach the bottom surface. In this way, since the overhangs 16a and the depositions 16b were formed on the projections of the irregularity 4b, and the film in the recesses of the irregularity was thin, a good coverage was not obtained.

Next, another film forming process was performed by applying a voltage of 550 W (2,800 V-0.2 A) to the ion gun 11, and by irradiating an ion beam to the substrate 4 from the ion gun 11. That is, sputtering and ion beam irradiation were alternately performed successively with the rotating drum 3 being rotated. The results are shown in FIG. 9 and FIG. 10.

When a Ni film 17 having a thickness 200 nm was formed on the substrate 4-1, as shown in FIG. 9, no overhangs were formed on the projections of the irregularity 4a, and a Ni film 17 of a uniform thickness was formed in the recesses. Due to the uniform thickness, wiring can be stably filled in the recesses.

When a Ni film 18 having a thickness 500 nm was formed on the substrate 4-2, as shown in FIG. 10, no overhangs or depositions were formed on the projections of the irregularity 4b. A Ni film 18 of a uniform thickness was formed on the sidewalls of the recesses of the irregularity 4b and also a Ni film 18 of a desired thickness was formed on the bottom surfaces of the recesses. This means the film over the tops of the projections and the film on the bottom surfaces of the recesses have almost the same thickness. In this way, a Ni film 18 of a uniform and desired thickness was formed following the contours of the irregularity 4b, which resulted in a good coverage.

There is a mechanism (action) in which the operation of the ion gun 11 leads to the improvement in the filling characteristics and coverage, as follows.

If the ion gun 11 is not operated, as described above, the opening of a recess is closed by the overhang 15a, 16a and the deposition 16b, and this makes it difficult for the sputtered particles to reach all over the surface (sidewalls and bottom surface) of the recess. To the contrary, when the ion gun 11 is operated, an ion beam from the ion gun 11 is irradiated to the overhang 15a, 16a and the deposition 16b, to etch (flicked and removed) the overhang 15a, 16a and the deposition 16b. Though the ion beam is irradiated to the remained portions (such as the top of a projection, the sidewall of a recess) as well, the laterally protruded overhang 15a, 16a and the deposition 16b are more likely to be subjected to the irradiation. That is, more irradiation goes to the overhang 15a, 16a and the deposition 16b, and less irradiation goes to the sidewall and bottom surface of a recess. This results in more etching of the overhang 15a, 16a and the deposition 16b, and the sidewall and bottom surface of a recess remains with a less etched film.

After the etching process, sputtered particles jump into the surface of the substrate 4 when the substrate 4 comes again to the position to oppose the Ni target 5 as the rotating drum 3 rotates. Since the overhang 15a, 16a and the deposition 16b are already etched, the recess has an opening wide enough to allow the sputtered particles to reach the sidewall and bottom surface of the recess. Subsequently when the substrate 4 comes again to the position to oppose the ion gun 11 as the rotating drum 3 rotates, the overhang 15a, 16a and the deposition 16b which were again formed by the previous sputtering are to be etched.

In this way, sputtering and etching are alternately performed successively to selectively etch the overhang 15a, 16a and the deposition 16b, which enables an effective forming of a Ni film both on the sidewall and the bottom surface of a recess. This is the mechanism in which a Ni film with the improved filling characteristics and coverage is formed on the substrate 4 with irregularity as described above.

While an Ar gas which is highly effective in etching is used to produce an ion beam in this embodiment, Ne, Kr, and Xe may be used. An energy range of the ion beam, a way to hold the substrate 4, sputtering means, and the number of the ion guns 11 may be selected as in Embodiment 1 above described.

In this embodiment, the way to improve the filling characteristics and coverage of the substrate 4 with irregularity is explained, and the comparison results on a surface roughness of a film are not shown. However, similarly as in Embodiment 1, the ion beam effectively etches the projections of roughness on a film to reduce the surface roughness. The result of reduced surface roughness can be obtained without the oxidation reaction by the ECR reaction chamber 30. Therefore, in this embodiment also, the reduced surface roughness of a film may cause an effect of higher transmittance.

### Embodiment 4

In this embodiment, a film forming process was performed on a substrate 4-3 having a surface with irregularity 4c the aspect ration of which is relatively large, using different types and amounts of gases which are introduced through a gas introducing inlet port for an ion gun 12, with the film forming apparatus 1 according to Embodiment 1.

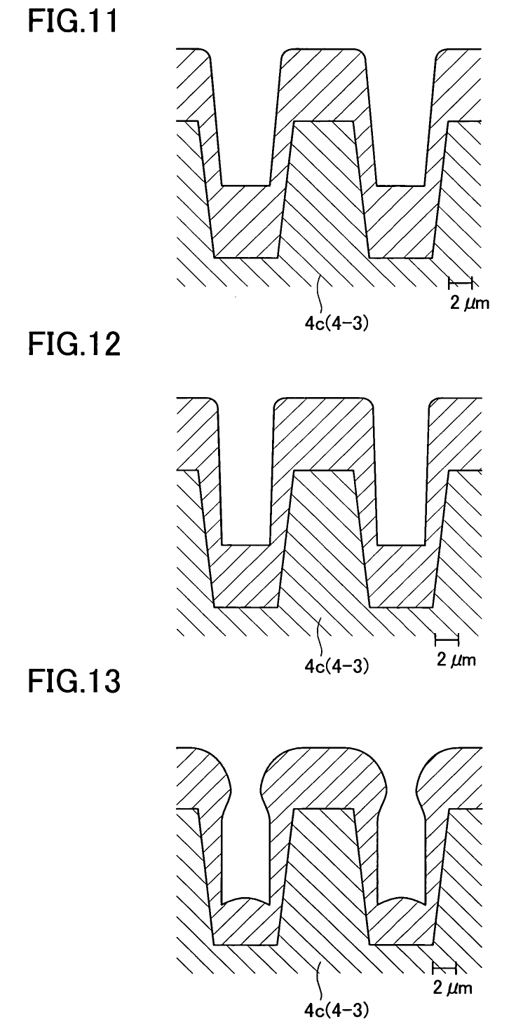

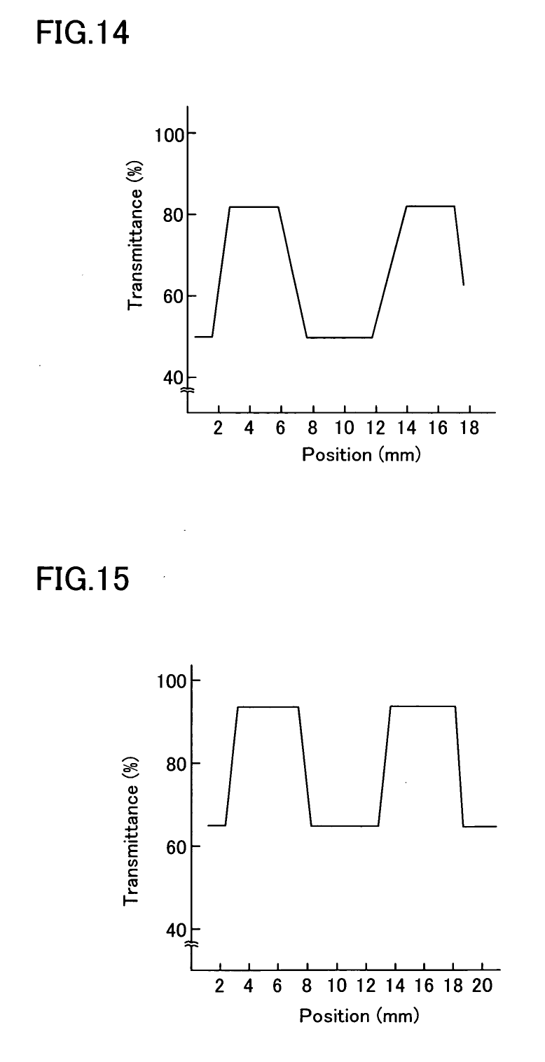

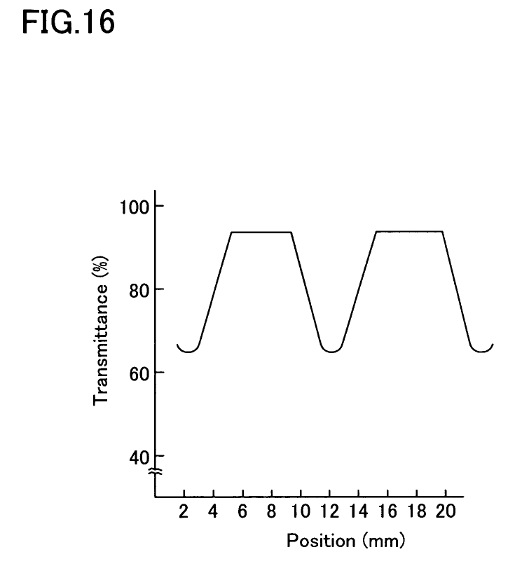

FIG. 11 to FIG. 13 are respectively a cross-sectional view of a film stack which is formed with the introduction of an Ar gas 30 sccm, an Ar gas 10 sccm and an O₂ gas 20 sccm, and an O₂ gas 30 sccm. FIG. 14 to FIG. 16 respectively show a transmittance measured by scanning the beam light having a diameter of 1 μm onto the surface of the substrate 4-3 shown in FIG. 11 to FIG. 13, and FIG. 14 corresponds to FIG. 11, FIG. 15 corresponds to FIG. 12, and FIG. 16 corresponds to FIG. 13.

When an Ar gas 30 sccm is introduced, as shown in FIG. 14, the transmittance changes at almost the same period corresponding to the change of the irregularity 4c of the substrate 4-3, and the transmittance value was about from 50% to 82%. The transmittance changes in steps because it corresponds to the beam light absorption into the thickness of the substrate 4-3 and the depositioned film on the substrate 4-3. When an Ar gas 10 sccm and an O₂ gas 20 sccm are introduced, as shown in FIG. 15, the transmittance changes at almost the same period corresponding to the change of the irregularity 4c of the substrate 4-3, and the transmittance value was high and about from 65% to 95%. The transmittance changes in steps because it corresponds to the beam light absorption into the thickness of the substrate 4-3 and the depositioned film on the substrate 4-3. This means the formed film follows the contour of the substrate 4-3, and has a higher transmittance than those in FIG. 11 and FIG. 14. When an O₂ gas 30 sccm is introduced, as shown in FIG. 16, the recesses grew extremely narrow, and the projections grew extremely wide for the irregularity 4c of the substrate 4-3, and the formed film did not follow the contour of the substrate 4-3.

Thus, when an Ar gas 30 sccm is introduced (FIG. 11 and FIG. 14), the etching described in above Embodiment 3 works well, which allows a film forming process to be performed on a substrate having steps such as the irregularity 4c to form a film which follows the contour of the substrate. However, the beam plasma (ion beam) without oxygen does not act to accelerate the oxidation reaction of the metal film, which causes insufficient oxidation of the film, and the absorbed light is remained inside of the film, resulting in a low film transmittance.

To the contrary, when an Ar gas 10 sccm and an O₂ gas 20 sccm are introduced (FIG. 12 and FIG. 15), the etching works well, which allows a film forming process to be performed on a substrate having steps such as the irregularity 4c to form a film which follows the contour of the substrate. In addition, the beam plasma with oxygen acts to accelerate the oxidation reaction of the metal film, which causes sufficient (complete) oxidation of the film, and less absorbed light is remained inside of the film, resulting in a high film transmittance.

When an O₂ gas 30 sccm is introduced (FIG. 13 and FIG. 16), the oxygen in the beam plasma accelerates the oxidation reaction of the metal film, resulting in a film having a high film transmittance. However, since the effect of the etching is insufficient with only O₂, as shown in FIG. 13, an overhang is formed at the shoulder of a recess of the irregularity 4c. This causes light scattering and reflecting when the beam light is irradiated to the recess, and the transmittance pattern following the contour of the substrate 4-3 is not obtained.

The above results show that both the etching effect and the reaction acceleration effect can be obtained in combination by setting the amount of the rare gas such as Ar for introducing into the ion gun 11 and the amount of the reactivity gas such as O₂ in an appropriate range respectively.

### INDUSTRIAL APPLICABILITY

The present invention may be applied to form a film on a substrate of a polarized filtering element which is used in the optical communication field and the like.

1. A film forming apparatus, characterized in that the apparatus comprises, in an evacuatable vacuum chamber:
a holding member to hold a substrate;
film forming means to form a thin film on the substrate;
reacting means to react the thin film with a reaction gas by plasma; and an ion gun to irradiate an ion beam to the substrate, and the apparatus forms a thin film stack by one of accelerating of the reaction between the thin film and the reaction gas and etching of a portion of the thin film, or by both accelerating of the reaction between the thin film and the reaction gas and etching of a portion of the thin film.

2. The film forming apparatus according to claim 1, wherein the holding member is a tubular rotating drum rotatable on an axis, and the substrate is held on an outer circumferential surface of the rotating drum.

3. The film forming apparatus according to claim 1, wherein the holding member is a flat plate rotary disk which rotates on a center axis, and the substrate is held on a plate surface of the rotary disk.

4. The film forming apparatus according to claim 1, wherein a plurality of film forming means are provided.

5. The film forming apparatus according to claim 1, wherein the film forming means and the reacting means form one of an oxide film and a nitride film, or both an oxide film and a nitride film.

6. The film forming apparatus according to claim 1, wherein the film forming means is a means for sputtering.

7. The film forming apparatus according to claim 1, wherein an accelerating voltage applied to the ion gun is 500 V to 3,000 V.

8. The film forming apparatus according to claim 1, wherein a gas to produce the ion beam is one of an oxidizing gas to supply oxygen ions and a nitriding gas to supply nitrogen ions.

9. The film forming apparatus according to claim 1, wherein the ion beam is generally perpendicularly irradiated to the substrate.

10. The film forming apparatus according to claim 1, wherein the ion beam is irradiated toward the thin film which blocks a thin film deposition into a recess of an irregular surface of the substrate.

11. A film forming method, characterized in that the method comprises:
a film forming step to form a thin film on a substrate which is held on a holding member in an evacuatable vacuum chamber;
a reacting step to react the formed thin film with a reaction gas by plasma; and
an irradiating step to irradiate an ion beam by an ion gun to the substrate, and
the irradiating step further comprises forming a thin film stack by one of accelerating the reaction between the thin film and the reaction gas and etching a portion of the thin film, or by both of accelerating the reaction between the thin film and the reaction gas and etching a portion of the thin film.

12. The film forming method according to claim 11, wherein the holding member is a tubular rotating drum rotating on an axis, and further comprising holding the substrate on an outer circumferential surface of the rotating drum, and rotating the drum while the thin film is formed and stacked in the film forming step, the reacting step, and the irradiating step.

13. The film forming method according to claim 11, wherein the holding member is a flat plate rotary disk rotating on an axis, and further comprising holding the substrate on a plate surface of the rotary disk, and rotating the rotary disk while the film forming step, the reacting step, and the irradiating step are performed to form and stack the thin film.

14. The film forming method according to claim 11, wherein the film forming step is a step to form a plurality of thin films by a plurality of film forming means.

15. The film forming method according to claim 11, wherein one of an oxide film and a nitride film, or both an oxide film and a nitride film are formed in the film forming step and the reacting step.

16. The film forming method according claim 11, wherein the film forming step is a step to form a thin film by sputtering.

17. The film forming method according claim 11, comprising applying an accelerating voltage to the ion gun of 500 V to 3,000 V.

18. The film forming method according claim 11, wherein the gas to produce the ion beam is one of an oxidizing gas to supply oxygen ions and a nitriding gas to supply nitrogen ions.

19. The film forming method according to claim 11, comprising irradiating the ion beam generally perpendicularly to the substrate.

20. The film forming method according to claim 11, wherein the ion beam is irradiated toward the thin film which blocks a thin film deposition into a recess of an irregular surface of the substrate.
